(19) United States
(12) Patent Application Publication
(10) Pub. No.: US 2005/0266319 A1
(43) Pub. Date: Dec. 1, 2005

(54) Patterning substrate and cell culture substrate

(75) Inventors: Hideyuki Miyake, Tokyo (JP); Hideshi Hattori, Tokyo (JP); Hironori Kobayashi, Tokyo (JP)

Correspondence Address: SEYFARTH SHAW LLP, 55 EAST MONROE STREET, SUITE 4200, CHICAGO, IL, 60603-5803, US

(73) Assignee: Dai Nippon Printing Co., Ltd.

(21) Appl. No.: 11/044,700

(22) Filed: Jan. 27, 2005

(30) Foreign Application Priority Data
Jan. 28, 2004 (JP) 2004-020254

(51) Int. Cl. G03F 1/00; B44C 1/22

(52) U.S. Cl. 430/5; 430/313; 216/41

(57) ABSTRACT

The present invention intends primarily to provide such as cells culture patterning substrate that is used to adhere a cell in a highly precise pattern on a base material to culture and a cell culture substrate on which cells are adhered in a high precision pattern. To attain the object, the invention provides a patterning substrate comprising: a base material; and a cell adhesive layer formed on the base material and comprising a cell adhesive material which has cell adhesive properties and is decomposed or denatured by action of a photocatalyst on the basis of irradiation with energy, and a binder.

### BACKGROUND OF THE INVENTION

1. Field of the Invention

The present invention relates to a cell culture patterning substrate capable of adhering cells in a highly precise pattern, a patterning substrate used for forming the cell culture patterning substrate, a coating liquid for patterning substrate used for forming the patterning substrate, and a cell culture substrate on which cells are adhered in a highly precise pattern.

2. Description of the Related Art

At present, cell cultures of various animals and plants are performed, and also new cell culture methods are in development. The technologies of the cell culture are utilized, such as to elucidate the biochemical phenomena and natures of cells and to produce useful substances. Furthermore, with cultured cells, an attempt to investigate the physiological activity and toxicity of artificially synthesized medicals is under way.

Some cells, particularly a lot of animal cells have the adhesion dependency of adhering to some materials and growing thereon, and cannot survive for a long period under a flotation condition out of organisms. For culturing cells having such adhesion dependency, a carrier to which cells can adhere is necessary, and in general, a plastic culturing plate with uniformly applied cell adhesive proteins such as collagen, fibronectin and the like is used. It is known that these cell adhesive proteins act on cultured cells, make the cells adhere easily, and exert an influence on the form of cells.

On the other hand, there is a technology reported of adhering cultured cells only onto a small part on a base material and arranging them. By such a technology, it is made possible to apply cultured cells to artificial organs, biosensors, bioreactors and the like. As the method of arranging cultured cells, there is a method adopted in which a base material having a surface that forms a pattern different in easiness of adhesion to cells is used, cells are cultured on the surface of this base material and allowed to adhere only onto surfaces processed so that cells adhere, and thereby the cells are arranged.

For example, in Japanese Patent Application Laid-Open (JP-A) No. 2-245181, an electric charge-retaining medium on which an electrostatic pattern is formed is applied to culture cells for the purpose of proliferating nerve cells in a form of circuit, and the like. Furthermore, JP-A No. 3-7576 tries to arrange cultured cells on a surface on which a cell adhesion-inhibiting or cell adhesive photosensitive hydrophilic polymer has been patterned by a photolithography method.

Furthermore, JP-A No. 5-176753 discloses a cell culture base material on which a substance such as collagen and the like affecting on the adhesion ratio and form of cells is patterned, and a method of producing this base material by a photolithography method. By culturing cells on such a base material, a larger amount of cells can be adhered on a surface on which collagen or the like is patterned, to realize patterning of cells.

However, such patterning of cell culture regions may be required to be highly precise depending on applications. In the case of conducting patterning by such as a photolithography method using a photosensitive material as described above, a highly precise pattern can be obtained; however, a cell adhesive material is required to have photosensitivity, and it is difficult in many cases to conduct chemical modification to impart such photosensitivity to, for instance, biopolymers and the like; accordingly, there is a problem in that a range of selectivity of cell adhesive materials is extremely narrowed. Furthermore, in a photolithography method using a photo resist, it is necessary to use a liquid developer and the like, and these affect adversely in culturing cells in some cases.

Furthermore, as a method of forming a highly precise pattern of a cell adhesive material, a Micro Contact Printing method is proposed by George M. Whitesides, Harvard University (for example, U.S. Pat. Nos. 5,512,131 and 5,900,160 and JP-A Nos. 9-240125 and 10-12545). However, there is a problem in that it is difficult to industrially produce a cell culture base material having a pattern of a cell adhesive material using this method.

### SUMMARY OF THE INVENTION

In this connection, it is desired to provide a cell culture patterning substrate used to adhere and culture cells in a highly precise pattern on a base material, a cell culture substrate to which cells are adhered in a highly precise pattern, and the like.

The present invention provides a patterning substrate comprising: a base material; and a cell adhesive layer formed on the base material and comprising a cell adhesive material which has cell adhesive properties and is decomposed or denatured by action of a photocatalyst on a basis of irradiation with energy, and a binder.

According to the invention, the cell adhesive layer comprises the cell adhesive material; therefore, the patterning substrate can be rendered a patterning substrate capable of forming a region not having cell adhesive properties, where the cell adhesive material is decomposed or denatured, and a region good in cell adhesive properties, where the cell adhesive material remains, by using, for example, a photocatalyst-containing layer comprising a photocatalyst to irradiate energy in a pattern form onto the cell adhesive layer.

In the invention, a light-shielding portion is formed on the base material. According to this, for example, in the case of making the cell adhesive layer and a photocatalyst-containing layer which comprises a photocatalyst facing each other to irradiate energy onto the resultant from the side of the base material, only the region where the light-shielding portion is not formed can be irradiated with the energy to decompose or denature the cell adhesive material therein.

The invention also provides a cell culture patterning substrate, wherein the cell adhesive layer of the above-mentioned patterning substrate comprises a cell adhesion-inhibiting portion wherein the cell adhesive material is decomposed or denatured in a pattern form and a cell adhesion portion which is a region other than the cell adhesion-inhibiting portion.

According to the invention, the cell culture patterning substrate comprises the cell adhesion-inhibiting portion poor in cell adhesive properties, where the cell adhesive material is decomposed or denatured, and the cell adhesion portion good in cell adhesive properties, where the cell adhesive material is not decomposed or denatured; therefore, the cell culture patterning substrate can be rendered a cell culture patterning substrate capable of causing cells to adhere highly precisely only onto the cell adhesion portion without using any complicated step, any treating solution or the like that produces a bad effect on cells.

The present invention also provides a cell culture substrate, wherein cells adhere onto the cell adhesion portion of the above-mentioned cell culture patterning substrate.

According to the invention, in the cell culture patterning substrate, the cell adhesion portion good in cell adhesive properties and the cell adhesion-inhibiting portion low in cell adhesive properties are formed; therefore, cells can be caused to adhere easily only onto the cell adhesion portion so as to produce a cell culture substrate onto which the cells adhere in a highly precise pattern form. In this case, the cell culture substrate does not need to contain therein any photocatalyst; accordingly, the culture substrate also has an advantage that there is no possibility that the cells are affected by any photocatalyst with the passage of time.

The present invention also provides a coating liquid for patterning substrate comprising a cell adhesive material which has cell adhesive properties and is decomposed or denatured by action of a photocatalyst on a basis of irradiation with energy, and a material having cell adhesion-inhibiting properties of inhibiting adhesion to cells at least after the material is irradiated with energy.

According to the invention, by applying the coating liquid for patterning substrate onto a base material or the like to form a layer, the layer can be rendered a layer good in cell adhesive properties on the basis of the cell adhesive material. By using/setting, to this layer, for example, a photocatalyst-containing layer comprising a photocatalyst and then irradiating the layer with energy, the cell adhesive material can be decomposed or denatured; and further the layer comprises the cell adhesion-inhibiting material. For these reasons, the cell adhesive properties of the region irradiated with the energy can be made low. Accordingly, this coating liquid for patterning substrate is a coating liquid capable of forming easily a region good in cell adhesive properties and a region low in cell adhesive properties.

The invention also provides a method for producing a cell culture patterning substrate, comprising:
a cell adhesive layer forming process of forming, on a base material, a cell adhesive layer comprising a cell adhesive material which has cell adhesive properties and is decomposed or denatured by action of a photocatalyst on a basis of irradiation with energy, and a binder; and an energy irradiating process of arranging the cell adhesive layer and a photocatalyst-containing layer side substrate having a base body and a photocatalyst-containing layer comprising the photocatalyst to dispose the cell adhesive layer and the photocatalyst-containing layer facing each other, and subsequently irradiating the energy onto a resultant from a given direction to form a pattern composed of a cell adhesion-inhibiting portion where the cell adhesive material comprised in the cell adhesive layer is decomposed or denatured, and a cell adhesion portion which is other than the cell adhesion-inhibiting portion.

According to the invention, the cell adhesive layer formed in the cell adhesive layer forming process comprises the cell adhesive material; therefore, when the photocatalyst-containing layer side substrate is used to irradiate energy in a pattern form in the energy irradiating process, it is possible to form easily a cell adhesion-inhibiting portion, where the cell adhesive material is decomposed or denatured, and a cell adhesion portion good in cell adhesive properties, on which no energy is irradiated. Thus, a cell culture patterning substrate having these portions can be produced. According to the invention, because of the use of the photocatalyst-containing layer side substrate, the cell culture patterning substrate does not need to comprise therein any photocatalyst. Thus, for example, even if cells adhere onto the cell adhesion portion, it is possible to produce a high-quality cell culture patterning substrate, wherein the cells are not affected by any photocatalyst with the passage of time.

The invention also provides a method for producing a cell culture substrate, comprising a cell adhesion process of causing cells to adhere onto the cell adhesion portion of the cell culture patterning substrate produced by the above-mentioned the cell culture patterning substrate producing method.

According to the invention, the cell adhesion portion good in cell adhesive properties and the cell adhesion-inhibiting portion low in cell adhesive properties are formed on the cell culture patterning substrate; it is therefore possible to easily produce a cell culture substrate wherein cells adhere highly precisely only onto the cell adhesion portion.

The invention also provides a method for producing a cell culture substrate comprising a base material, a cell adhesive layer formed on the base material and comprising a cell adhesive material which has cell adhesive properties and is decomposed or denatured by action of a photocatalyst on a basis of irradiation with energy and a binder, and cells formed in a pattern on the cell adhesive layer; the cell adhesive layer having a cell adhesion-inhibiting portion where the cell adhesive material is decomposed or denatured, and a cell adhesion portion which is other than the cell adhesion-inhibiting portion, and the cells being formed on the cell adhesion portion;
comprising a cell adhesion process of causing the cells to adhere onto the cell adhesion portion, and a subsequent cell maintaining process of arranging a photocatalyst-containing layer side substrate having a base body and a photocatalyst-containing layer comprising the photocatalyst onto the cell adhesion-inhibiting portion to dispose the cell adhesive layer and the photocatalyst-containing layer facing each other, and subsequently irradiating the energy onto a resultant from a given direction to maintain the pattern of the cells adhering onto the cell adhesion portion.

According to the invention, cells are caused to adhere onto the cell adhesion portion in the cell adhesion process and subsequently the photocatalyst-containing layer side substrate is used to irradiate energy onto the cell adhesion-inhibiting portion of the cell culture substrate in the cell maintaining process. In this way, the cells or the like adhering onto the cell adhesion-inhibiting portion can be removed, so as to produce a cell culture substrate wherein the cells adhere in a highly precise pattern form only onto the cell adhesion portion.

### BRIEF DESCRIPTION OF THE DRAWINGS

FIG. 1 is a schematic sectional view showing an example of the patterning substrate of the present invention.

FIG. 2 is a schematic sectional view showing another example of the patterning substrate of the invention.

FIG. 3 is a schematic sectional view showing an example of the cell culture patterning substrate of the invention.

FIG. 4 is a schematic sectional view showing another example of the cell culture patterning substrate of the invention.

FIGS. 5A to 5C are process charts showing an example of a method for forming cell adhesion-inhibiting portions in the cell culture patterning substrate of the invention.

FIG. 6 is a schematic sectional view showing an example of the photocatalyst-containing layer side substrate used in the invention.

FIG. 7 is a schematic sectional view showing another example of the photocatalyst-containing layer side substrate used in the invention.

FIG. 8 is a schematic sectional view showing still another example of the photocatalyst-containing layer side substrate used in the invention.

FIG. 9 is a schematic sectional view showing an example of the cell culture substrate of the invention.

FIG. 10 is a schematic sectional view showing an example of the energy irradiating process in the method of the invention for producing a cell culture substrate.

FIG. 11 is a schematic sectional view showing another example of the energy irradiating process in the method of the invention for producing a cell culture substrate.

FIG. 12 is a schematic sectional view showing still another example of the energy irradiating process in the method of the invention for producing a cell culture substrate.

FIGS. 13A and 13B are each a schematic sectional view for explaining a base material used in the cell culture patterning substrate of the invention.

### DESCRIPTION OF THE PREFERRED EMBODIMENTS

The present invention relates to such as a cell culture patterning substrate on which cells can be adhered in highly precise pattern, a patterning substrate that is used to form the cell culture patterning substrate, a coating liquid for patterning substrate that is used to form the patterning substrate, and a cell culture substrate on which cells are adhered in highly precise pattern. Hereinafter, these will be explained below separately.

A. Coating Liquid for Patterning Substrate

First, the coating liquid for patterning substrate of the present invention is described. This coating liquid for patterning substrate is a coating liquid comprising a cell adhesive material which has cell adhesive properties and is decomposed or denatured by action of a photocatalyst on the basis of irradiation with energy, and a cell adhesion-inhibiting material which has cell adhesion-inhibiting properties of inhibiting adhesion to cells at least after the material is irradiated with energy.

The coating liquid for patterning substrate of the invention comprises the cell adhesive material; therefore, in the case of applying the coating liquid for patterning substrate onto, for example, a base material or the like to form a layer, the cell adhesive properties of the layer can be made good. In the case of disposing, for example, a photocatalyst-containing layer comprising a photocatalyst facing the layer and then irradiating the resultant with energy, the cell adhesive material is decomposed or denatured by action of the photocatalyst on the basis of the irradiation with the energy so that the cell adhesive properties of the region irradiated with the energy can be made low. In this case, the coating liquid for patterning substrate comprises therein the cell adhesion-inhibiting material; therefore, the cell adhesive properties of the region irradiated with the energy can be made lower by the cell adhesion-inhibiting properties of the cell adhesion-inhibiting material. According to the invention, therefore, it is possible to render only the region not irradiated with the energy in the layer formed by the application of the coating liquid for patterning substrate a region onto which cells can be caused to adhere in a highly precise pattern form.

Each of the constituents used in the coating liquid for patterning substrate of the invention will be described hereinafter.

1. Cell Adhesive Material

First, a cell adhesive material used in the coating liquid for patterning substrate according to the present invention will be explained. The cell adhesive material used in the coating liquid for patterning substrate according to the present invention, as far as it has the adhesive properties with cells and can be decomposed or denatured by action of the photocatalyst on the basis of irradiation with energy, is not particularly restricted to the kind and the like. Here, the wording “has the cell adhesive properties” means being good in the cell adhesive properties, and, for instance, when the cell adhesive properties is different depending on the kind of cells, means to be good in the adhesive properties with target cells.

The cell adhesive material used in the present invention has such cell adhesive properties and can be decomposed or denatured by action of the photocatalyst on the basis of irradiation with energy such as to lose the cell adhesive properties or change to one that has the cell adhesion inhibiting properties that inhibit to adhere to cells.

As such materials having the cell adhesive properties, there are two kinds, one being materials having the cell adhesive properties owing to physicochemical characteristics and the other being materials having the cell adhesive properties owing to biochemical characteristics.

As physicochemical factors that determine the cell adhesive properties of materials having the cell adhesive properties owing to the physicochemical characteristics, the surface free energy, the electrostatic interaction and the like can be cited. For instance, in the case of the cell adhesive properties being determined by the surface free energy of the material, when the material has the surface free energy in a predetermined range, the adhesive properties between the cells and the material becomes good, and when it deviates from the above range the adhesive properties between the cells and material decreases. As such changes of the cell adhesive properties due to the surface free energy, experimental results such as shown in Data, for instance, CMC Publishing Co., Ltd. “Biomaterial no Saisentan”, Yoshito IKADA (editor), p. 109, lower part are known. As materials having the cell adhesive properties owing to such a factor, for instance, hydrophilic polystyrene, poly (N-isopropyl acrylamide) and the like can be cited. When such a material is used, by action of the photocatalyst on the basis of irradiation with energy, for instance, a functional group on a surface of the material is substituted, decomposed or the like to cause a change in the surface free energy, resulting in one that does not have the cell adhesive properties or one that has the cell adhesion inhibiting properties.

When the adhesive properties between cells and a material is determined owing to the electrostatic interaction or the like, for instance, the cell adhesive properties can be determined owing to an amount of positive electric charges and the like that the material has. As materials having the cell adhesive properties owing to such electrostatic interaction, basic polymers such as polylysine, basic compounds such as aminopropyltriethoxysilane, N-(2-aminoethyl)-3-aminopropyltrimethoxysilane and condensates and the like including these can be cited. When such materials are used, by action of the photocatalyst on the basis of irradiation with energy, the above-mentioned materials are decomposed or denatured, thereby, for instance, an amount of positive electric charges present on a surface can be altered, resulting in one that does not have the cell adhesive properties or one that has the cell adhesion inhibiting properties.

As materials having the cell adhesive properties owing to the biological characteristics, ones that are good in the adhesive properties with particular cells, ones that are good in the adhesive properties with many cells, or the like can be cited. Specifically, fibronectin, laminin, tenascin, vitronectin, RGD (arginine-glycine-asparagine acid) sequence containing peptide, YIGSR (tyrosine-isoleucine-glycine-serine-arginine) sequence containing peptide, collagen, atelocollagen, gelatin and the like can be cited. When such materials are used, by action of the photocatalyst on the basis of irradiation with energy, for instance, a structure of the material is partially destroyed, a principal chain is destroyed or the like, resulting in one that does not have the cell adhesive properties or one that has the cell adhesion inhibiting properties.

The amount of the cell adhesive material is appropriately optimized in accordance with the cell adhering ability of the material. Usually, the content by percentage thereof in the coating liquid for patterning substrate is preferably from 0.0001 to 30% by weight, more preferably from 0.001 to 10% by weight. This makes it possible to render the region comprising the cell adhesive material a region good in cell adhesive properties.

2. Cell Adhesion-Inhibiting Material

The following will describe the cell adhesion-inhibiting material used in the coating liquid for patterning substrate of the invention. The cell adhesion-inhibiting material used in the coating liquid for patterning substrate of the invention is a material having cell adhesion-inhibiting properties of inhibiting adhesion to cells at least after the material is irradiated with energy. The cell adhesion-inhibiting properties mean natures that at the time of applying the coating liquid for patterning substrate to form a layer, cells are inhibited from adhering onto any region, in the layer, irradiated with energy. When adhesive properties to cells are different in accordance with the kinds of the cells or the like, the cell adhesion-inhibiting properties mean natures that the layer has natures of inhibiting the layer from adhering onto target one out of the cells.

In the present invention, the cell adhesion-inhibiting material is not limited to any special kind or the like if the material has such cell adhesion-inhibiting properties at least after the irradiation thereof with energy. The material may be, for example, a material having cell adhesion-inhibiting properties before the irradiation thereof with energy, a material which does not have cell adhesion-inhibiting properties before the irradiation thereof with energy but gives low cell adhesive properties by action of a photocatalyst on the basis of irradiation with energy to exhibit cell adhesion-inhibiting properties, or some other material.

In the invention, it is particularly preferred to use a cell adhesion-inhibiting material which is converted to a material having cell adhesion-inhibiting properties by action of a photocatalyst on the basis of irradiation with energy. This makes it possible to make only the region irradiated with the energy low in cell adhesive properties without inhibiting the cell adhesive properties of the cell adhesive material in the region not irradiated with the energy.

The material used as such cell adhesion-inhibiting material is preferably, for example, a material which has such a high bonding energy that the main skeleton thereof is not decomposed by photoexcitation of the photocatalyst and which has an organic substituent as decomposed by action of the photocatalyst. Examples thereof include (1) organopolysiloxane which is obtained by hydrolyzing or polycondensating chloro- or alkoxy-silane or the like by such as sol-gel reaction and exhibits a large strength; and (2) organopolysiloxane which is obtained by crosslinking reactive silicone and is excellent in water repellency or oil repellency.

In the case of the (1), it is preferable to be organopolysiloxane that is a hydrolysis condensate or cohydrolysis condensate of at least one kind of silicon compounds expressed by a general formula:
YₙSiX₍₄₋ₙ₎
(Here, Y denotes an alkyl group, vinyl group, amino group, phenyl group or epoxy group, and X denotes an alkoxyl group, acetyl group or halogen. n is an integer of 0 to 3). The number of carbons of the group expressed with Y is preferably in the range of 1 to 20, and the alkoxy group expressed with X is preferably a methoxy group, ethoxy group, propoxy group or butoxy group.

As the reactive silicone according to the (2), compounds having a skeleton expressed by a general formula below can be cited.

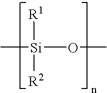

In the above general formula, n is an integer of 2 or more, R¹ and R² are each a substituted or unsubstituted alkyl, alkenyl, aryl or cyanoalkyl group having 1 to 20 of carbon atoms, and 40% or less by mole ratio of the whole thereof is composed of vinyl, phenyl and halogenated phenyl. A compound wherein R¹ and R² are each a methyl group is preferred since the surface energy thereof becomes the smallest; and it is preferred that 60% or more by mole ratio of the whole is methyl groups. The reactive silicone compound has, in the molecular chain thereof, at least one reactive group, such as a hydroxyl group, at a chain terminal or side chain thereof. The use of a material as described above makes it possible to render the surface of the region irradiated with energy a surface having a high hydrophilicity by action of the photocatalyst on the basis of the irradiation with the energy. According to this high hydrophilicity, it is possible to inhibit adhesion of cells so as to render the region irradiated with the energy a region onto which cells are not to adhere.

In the case of using the above-mentioned material as the cell adhesion-inhibiting material, the contact angle thereof with water is preferably from 15 to 120°, more preferably from 20 to 100° before the material is irradiated with energy. According to this, the cell adhesion-inhibiting material can be rendered a material which does not inhibit the cell adhesive properties of the above-mentioned cell adhesive material.

In the case of irradiating this cell adhesion-inhibiting material with energy, it is preferred that the contact angle thereof with water becomes 10° or less. This range makes it possible to render the material having a high hydrophilicity and low cell adhesive properties.

The contact angle with water referred to herein is a result obtained by using a contact angle measuring device (CA-Z model, manufactured by Kyowa Interface Science Co., Ltd.) to measure the contact angle of the material with water or a liquid having a contact angle equivalent to that of water (after 30 seconds from the time when droplets of the liquid are dropped down from its micro syringe), or a value obtained from a graph prepared from the result.

Furthermore, it is allowable to incorporate, into a binder, a stable organosilicon compound which does not undergo any crosslinking reaction, such as dimethylpolysiloxane, together with the above-mentioned organopolysiloxane.

In the present invention, it is allowable to use, together with the above-mentioned cell adhesion-inhibiting material, a decomposition material or the like which causes such as a change in the wettability of the region irradiated with energy so as to make the cell adhesive properties thereof low, or which assists such a change.

As such decomposition substances, for instance, surfactants or the like that are decomposed and the like by action of a photocatalyst on the basis of irradiation with energy to be hydrophilic and the like to result in lowering the cell adhesive properties can be cited. Specifically, hydrocarbons of the respective series of NIKKO L BL, BC, BO, and BB manufactured by Nikko Chemicals Co., Ltd., and silicone base nonionic surfactants such as ZONYL FSN and FSO manufacture by Du Pont Kabushiki Kaisha, Surflon S-141 and 145 manufactured by ASAHI GLASS CO., LTD., Megaface F-141 and 144 manufactured by DAINIPPON INK AND CHEMICALS, Inc., FTERGENT F-200 and F251 manufactured by NEOS, UNIDYNEDS-401 and 402 manufactured by DAIKIN INDUSTRIES, Ltd., and Fluorad FC-170 and 176 manufactured by 3M can be cited, and cationic surfactants, anionic surfactants and amphoteric surfactants also can be used.

Besides the surfactants, the following can also be given as examples of the decomposition material: polyvinyl alcohol, polyethylene glycol, amphoteric ion materials having a betaine structure, phospholipid-containing materials such as poly(2-methacryloyloxyethyl)phosphorylcholine, and oligomers and polymers such as poly (2-methoxyethyl) acrylate, unsaturated polyester, acrylic resin, polyethylene, diallyl phthalate, ethylene propylene diene monomer, epoxy resin, phenol resin, polyurethane, melamine resin, polycarbonate, polyvinyl chloride, polyamide, polyimide, styrene butadiene rubber, chloroprene rubber, polypropylene, polybutylene, polystyrene, polyvinyl acetate, nylon, polyester, polybutadiene, polybenzimidazole, polyacrylonitrile, epichlorohydrin, polysulfide, and polyisoprene.

In the invention, the content by percentage of the cell adhesion-inhibiting material in the coating liquid for patterning substrate is preferably from 0.001 to 60% by weight, more preferably from 0.01 to 40% by weight, and even more preferably from 0.1 to 20% by weight.

3. Coating Liquid for Patterning Substrate

The following will describe the coating liquid for patterning substrate of the present invention. This coating liquid for patterning substrate is not limited to any special kind if the coating liquid contains the above-mentioned cell adhesive material and cell adhesion-inhibiting material. If necessary, the coating liquid may appropriately contain a binder and other components. The incorporation of the binder makes it possible to make easy the application of the coating liquid for patterning substrate onto, for example, a base material or the like and further give various properties, such as strength and resistance, to the formed layer. The binder may be appropriately selected in accordance with the use purpose of the coating liquid for patterning substrate. In the invention, the cell adhesion-inhibiting material preferably fulfills the role of this binder.

It is preferred that the coating liquid for patterning substrate of the invention does not contain any photocatalyst. This makes the following possible: for example, in the case of causing cells to adhere onto the layer formed by the application of the coating liquid for patterning substrate, the resultant member is rendered a member wherein no photocatalyst produces an effect on the cells with the passage of time.

B. Patterning Substrate

The following will describe the patterning substrate of the present invention. The patterning substrate is a patterning substrate comprising a base material; and a cell adhesive layer formed on the base material and comprising a cell adhesive material which has cell adhesive properties and is decomposed or denatured by action of a photocatalyst on the basis of irradiation with energy, and a binder.

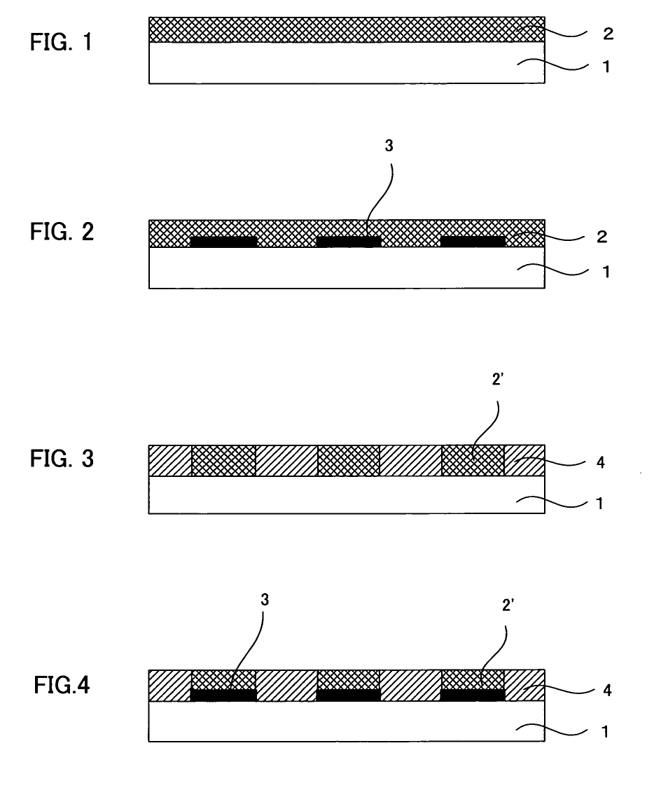

As shown in, for example, FIG. 1, in the patterning substrate of the invention, a cell adhesive layer 2 comprising the cell adhesive material and a binder as described above is formed on a base material 1. According to the invention, this cell adhesive layer comprises therein the cell adhesive material; therefore, for example, in the case of disposing such as a photocatalyst-containing layer comprising a photocatalyst face to the cell adhesive layer and then irradiating the resultant with energy, the cell adhesive material can be decomposed or denatured by action of the photocatalyst on the basis of the irradiation with the energy so that the region irradiated with the energy can be rendered a region not having cell adhesive properties. In the region not irradiated with the energy, the cell adhesive material remains; therefore, the region can be rendered a region having cell adhesive properties through the cell adhesive properties of the cell adhesive material. Consequently, it is possible to form a cell culture patterning substrate capable of forming a region good in cell adhesive properties and a region low in cell adhesive properties, without requiring any special device or complicated step, by irradiation with energy in a pattern form by use of the above-mentioned photocatalyst-containing layer or the like.

As shown in, for example, FIG. 2, the patterning substrate of the invention may be a patterning substrate wherein light-shielding portions 3 are formed on the base material 1. When such light-shielding portions are formed, only the cell adhesive material comprised in the cell adhesive layer on the regions where the light-shielding portions are not formed is decomposed or denatured by disposing, for example, a photocatalyst-containing layer comprising a photocatalyst face to the cell adhesive layer and then irradiating energy on the entire surface of the resultant from such as the base material side thereof. This makes it possible to irradiate energy in a pattern form onto the patterning substrate without using, for example, a photomask, so as to form regions onto which cells adhere easily and regions onto which no cells adhere.

The following will describe each of the constituents of the patterning substrate of the invention.

1. Cell Adhesive Layer

First, the cell adhesive layer used in the invention is described. The cell adhesive layer is not limited to any special kind if the layer is a layer which is formed on the base material that will be detailed later and which comprises a cell adhesive material that has cell adhesive properties and is decomposed or denatured by action of a photocatalyst on the basis of irradiation with energy, and a binder.

The cell adhesive layer may be, for example, a layer formed by use of a coating liquid comprising a cell adhesive material that has cell adhesive properties and is decomposed or denatured by action of a photocatalyst on the basis of irradiation with energy, and a binder. Specifically, the cell adhesive layer is preferably a layer formed by use of a coating liquid for patterning substrate which comprises a cell adhesive material and a cell adhesion-inhibiting material as a binder, as described in the item “A. Coating Liquid for Patterning Substrate”. This makes it possible that when the cell adhesive layer is irradiated with energy, the cell adhesive properties of the region irradiated with the energy are made lower and cells are caused to adhere in a highly precise pattern only onto the region not irradiated with the energy.

The method for forming such a cell adhesive layer may be a method of applying the above-mentioned coating liquid for patterning substrate in an ordinary coating manner or the like. Specifically, the coating manner which can be used may be spin coating, spray coating, dip coating, roll coating, bead coating or the like. An adsorbing process also can be preferably used.

For example, when concave portions are made in the base material that will be detailed later, there can be used a casting method of dropping down a coating liquid for patterning substrate or other solution into the concave portions in the base material and then drying the liquid to form the cell adhesive layer; an adsorbing method of dropping down a coating liquid for patterning substrate or other solution into the concave portions in the base material and washing the base material after a given time; or the like.

The cell adhesive material, the cell adhesion-inhibiting material and so on which are used in the cell adhesive layer used in the invention are the same as described in the above-mentioned item “A. Coating Liquid for Patterning Substrate”. Thus, the description thereof is omitted herein.

The film thickness of the cell adhesive layer is appropriately selected in accordance with the kind of the patterning substrate and others, and is usually from about 0.001 to 1 μm, preferably from about 0.005 to 0.1 μm.

It is preferred that the cell adhesive layer in the invention does not comprise therein any photocatalyst. This makes the following possible: for example, when cells adhere onto the cell adhesive layer, the cells are prevented from being affected by any photocatalyst with the passage of time to make the quality of the cell adhesive layer high. The method for decomposing or denaturing the cell adhesive material in this cell adhesive layer may be, for example, a method of disposing a photocatalyst-containing layer comprising a photocatalyst face to the cell adhesive layer and then irradiating the resultant with energy.

2. Base Material

The following will describe the base material used in the present invention. This base material is not limited to any special kind if the material is a material on which the cell adhesive layer can be formed. For example, the base material may be made of an inorganic material such as metal, glass or silicon, or an organic material, a typical example of which is plastic.

The flexibility and the like of the base material are properly selected according to the kind of the patterning substrate, applications, or the like. Furthermore, the transparency of the base material is properly selected depending on such as the kind of the patterning substrate, or a direction in which energy that is irradiated to decompose or denature the cell adhesive material is irradiated. For instance, when the base material has such as the light-shielding portion and the energy is irradiated from a base material side and the like, the base material has the transparency.

In the invention, the base material may be a flat base material or a base material wherein one or more concave portions are formed. The base material may be a base material wherein a single concave portion is formed as shown in FIG. 13A, or a base material wherein plural concave portions are formed as shown in FIG. 13B.

At this time, side walls of the base material having the concave portion(s) may be treated in such a manner that the cell adhesive layer will not be formed thereon. Examples of the method for such a treatment include a method of using a mask or the like to cause a material having liquid repellency to adhere only onto the side walls by CVD; and a method of causing a material having liquid repellency to adhere onto the entire surface of the concave portion(s) and then using a cylindrical mask or the like to conduct ultraviolet ray treatment, plasma treatment or some other treatment, thereby making only the bottom face(s) of the concave portion(s) lyophilic.

In the invention, the base material may be a base material washed with a chemical agent solution such as an alkali solution, or abase material subjected to dry washing, such as oxygen plasma treatment or ultraviolet ray treatment. In this case, the wettability of the above-mentioned coating liquid for patterning substrate is improved. This case also gives an advantage that the adhesive properties of the cell adhesive layer are improved since reactive functional groups are arranged on the surface of the base material.

On the base material according to the present invention, as mentioned above, a light-shielding portion may be formed. The light-shielding portion that can be used in the present invention, as far as it can shield energy that is irradiated on the patterning substrate, is not particularly restricted. For instance, a metal thin film that is made of chromium or the like and formed into a thickness of about 1000 to 2000 Å by a sputtering method, a vacuum deposition method or the like is formed and patterned to form a shielding portion. As the patterning method, an ordinary patterning method such as the sputtering can be used.

A method may be one by which a layer that contains light-shielding particles such as carbon particulates, metal oxides, inorganic pigments and organic pigments in a resin binder is formed in a pattern. As the resin binders that can be used, a polyimide resin, acrylic resin, epoxy resin, polyacrylamide, polyvinyl alcohol, gelatin, casein, cellulose and the like can be used singularly or in combination of two or more kinds, and furthermore a photosensitive resin and an O/W emulsion type resin composition such as emulsified reactive silicone can be used. A thickness of such the resinous light-shielding portion can be set in the range of 0.5 to 10 μm. As a method of patterning such the resinous light-shielding portion, methods such as a photolithography method and a printing method that are generally used can be used.

The light-shielding portions may be formed on the surface where the cell adhesive layer is formed out of surfaces of the base material, or may be formed on the opposite side surface. As shown in FIG. 2, it is preferred that the light-shielding portions 3 are formed on the surface where the cell adhesive layer 2 is formed out of surfaces of the base material 1 since the precision becomes good.

3. Patterning Substrate

The following will describe the patterning substrate of the present invention. The patterning substrate is not limited to any special kind if the patterning substrate is a patterning substrate wherein a cell adhesive layer is formed on the above-mentioned base material. The patterning substrate may be, for example, a patterning substrate wherein one or more different layers may be laminated as the need arises.

C. Cell Culture Patterning Substrate

The following will describe the cell culture patterning substrate of the present invention. The cell culture patterning substrate is a patterning substrate wherein the cell adhesive layer of the above-mentioned patterning substrate comprises a cell adhesion-inhibiting portion where the cell adhesive material is decomposed or denatured in a pattern form, and a cell adhesion portion which is an a region other than the cell adhesion-inhibiting portion.

As shown in, for example, FIG. 3, the cell culture patterning substrate of the present invention is a member which comprises a base material 1 and a cell adhesive layer formed on the base material 1, and has cell adhesion-inhibiting portions 4 not having cell adhesive properties, wherein the cell adhesive material comprised in the cell adhesive layer is decomposed or denatured, and cell adhesion portions 2′ good in cell adhesive properties, which are portions other than the cell adhesion-inhibiting portions.

According to the invention, cells can be caused to adhere easily only onto the cell adhesion portions since the patterning substrate comprises the cell adhesion portions and the cell adhesion-inhibiting portions. For example, even when cells are applied onto the entire surface of the cell adhesive layer, the cells can be caused to adhere highly precisely only onto the cell adhesion portions.

Moreover, according to the invention, by causing cells onto the cell adhesion portions and then arranging the cell adhesive layer and, for example, a photocatalyst-containing layer comprising a photocatalyst to face each other so as to irradiate energy onto the resultant from the base material side thereof, the cell adhesive material in the cell adhesion portions onto which the cells adhere can be decomposed or denatured. As a result, the cell adhesive properties of the portions can be made low. This makes it possible to peel the cells adhering onto the cell adhesion portions so as to yield cells formed in a pattern form. The energy irradiated at this time is set to such a degree that no cells are affected by the energy.

As shown in, for example, FIG. 4, in the invention, light-shielding portions 3 may be formed on the base material 1 to have the same pattern as the cell adhesion portions 2′ of the cell adhesive layer 2. The formation of such light-shielding portions makes the following possible: for example, by forming the patterning substrate described in the above-mentioned item “B. Patterning Substrate”, arranging a photocatalyst-containing layer comprising a photocatalyst to face the cell adhesive layer thereof and then irradiating energy onto the resultant from the base material side thereof, the cell adhesive material only on the regions where no light-shielding portions are formed is decomposed or denatured so as to form easily cell adhesion-inhibiting portions as described above.

Furthermore, in the case of causing cells to adhere onto the cell adhesion portions of the cell culture patterning substrate of the invention and then arranging the photocatalyst-containing layer as described above to face the cell adhesive layer thereof so as to irradiate energy onto the resultant from the base material side thereof, the energy can be irradiated only onto the cell adhesion-inhibiting portions. This makes the following possible: for example, even when cells adhere onto the cell adhesion-inhibiting portions, the cells on the cell adhesion-inhibiting portions are removed by the irradiation of the energy, so as to maintain a highly precise pattern.

Here, the cell adhesion portion is a region that contains a cell adhesive material that has the cell adhesive properties and can be decomposed or denatured by action of the photocatalyst on the basis of irradiation with energy, and a region good in the adhesive properties with target cells. Here, having the cell adhesive properties means to have the physicochemical cell adhesive properties or the biological cell adhesive properties such as explained in the section of “A. Coating Liquid for Patterning Substrate”.

On the other hand, the cell adhesion-inhibiting portions are regions low in cell adhesive properties where the cell adhesive material is decomposed or denatured. The wording “the cell adhesive material is decomposed or denatured” herein means that the cell adhesive material is not contained or the cell adhesive material is contained in a smaller amount than the amount of the cell adhesive material contained in the cell adhesion portions. When the cell adhesive material is, for example, a material which can be decomposed by action of the photocatalyst on the basis of irradiation with energy, the wording means that a small amount of the cell adhesive material is contained in the cell adhesion-inhibiting portions; a decomposition product or the like of the cell adhesive material is contained; the cell adhesive layer is completely decomposed and removed so that only the binder is contained; or the like. When the cell adhesive material is a material which can be denatured by action of the photocatalyst on the basis of irradiation with energy, the wording means that the denatured product or the like is contained in the cell adhesion-inhibiting portions. In the invention, it is preferred that the cell adhesion-inhibiting portions contain a cell adhesion-inhibiting material having cell adhesion-inhibiting properties such that adhesion to cells is inhibited. This makes it possible to make lower the cell adhesive properties of the cell adhesion-inhibiting portions so as to cause the cells to adhere highly precisely only onto the cell adhesion portions.

The base material and the cell adhesive layer used in the cell culture patterning substrate of the invention are the same as described in the above-mentioned item “Patterning Substrate”. Thus, description thereof is omitted herein. The following will describe the method for forming the cell adhesive layer having the cell adhesion portions and the cell adhesion-inhibiting portions.

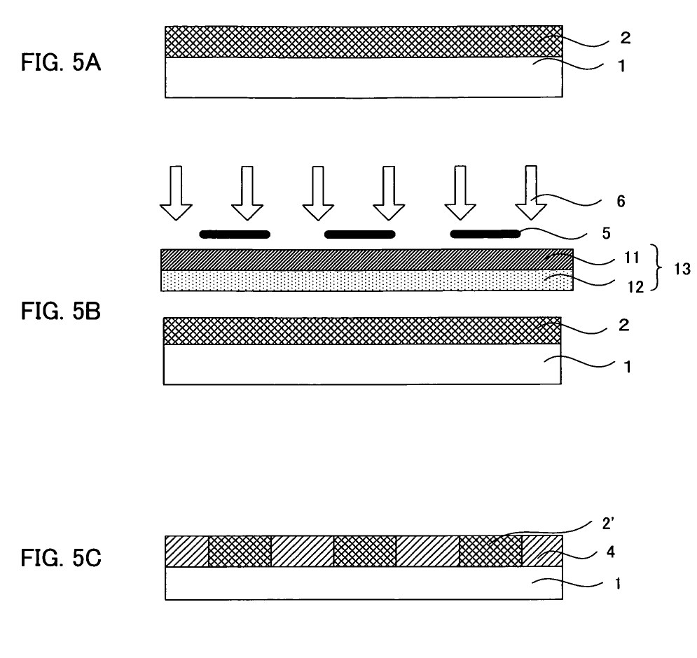

As shown in, for example, FIGS. 5A to 5C, the coating liquid for patterning substrate described in the above-mentioned item “A. Coating Liquid for Patterning Substrate” is first used to form a cell adhesive layer 2 comprising at least a cell adhesive material and a binder on a base material 1 (FIG. 5A). Next, prepared is a photocatalyst-containing layer side substrate 13 having a base body 11 and a photocatalyst-containing layer 12 which is formed on the base body 11 and comprises at least a photocatalyst. This photocatalyst-containing layer 12 and the cell adhesive layer 2 are arranged so as to face each other (FIG. 5B). Subsequently, energy 6 is irradiated, in a pattern form for forming cell adhesion-inhibiting portions, onto the resultant through a photomask 5 or the like (FIG. 5B). This makes it possible to form cell adhesion-inhibiting portions 4 low in cell adhesive properties, where the cell adhesive material comprised in the cell adhesive layer 2 is decomposed or denatured by action of the photocatalyst comprised in the photocatalyst-containing layer 12, and cell adhesion portions 2′ good in cell adhesive properties, where no energy is irradiated so that the cell adhesive material is not decomposed (FIG. 5C). The method and the like for forming the cell adhesive layer is the same method as described in the item “B. Patterning Substrate”. Thus, description thereof is omitted herein, and the following will describe the photocatalyst-containing layer side substrate, which is used to form the cell adhesion-inhibiting portions and comprises the photocatalyst-containing layer; energy; and so on.

(Photocatalyst-Containing Layer Side Substrate)

First, the photocatalyst-containing layer side substrate, which has a photocatalyst-containing layer comprising a photocatalyst, is described. The photocatalyst-containing layer side substrate used in the invention is normally a substrate having a photocatalyst-containing layer comprising a photocatalyst, and is usually a base body and substrate wherein a photocatalyst-containing layer is formed on the base body. This photocatalyst-containing layer side substrate may have, for example, photocatalyst-containing layer side light-shielding portions formed in a pattern form, a primer layer, or the like. The following will describe each of the constituents of the photocatalyst-containing layer side substrate used in the present process.

a. Photocatalyst-Containing Layer

First, the photocatalyst-containing layer used in the photocatalyst-containing layer side substrate is described. The photocatalyst-containing layer used in the invention is not limited to any special structure if the layer has a structure wherein the photocatalyst in the layer can cause the decomposition or denaturation of the cell adhesive material in the adjacent or near cell adhesive layer. The photocatalyst-containing layer may be made of a photocatalyst and a binder, or may be made only of a photocatalyst. The property of the surface thereof may be lyophilic or repellent to liquid.

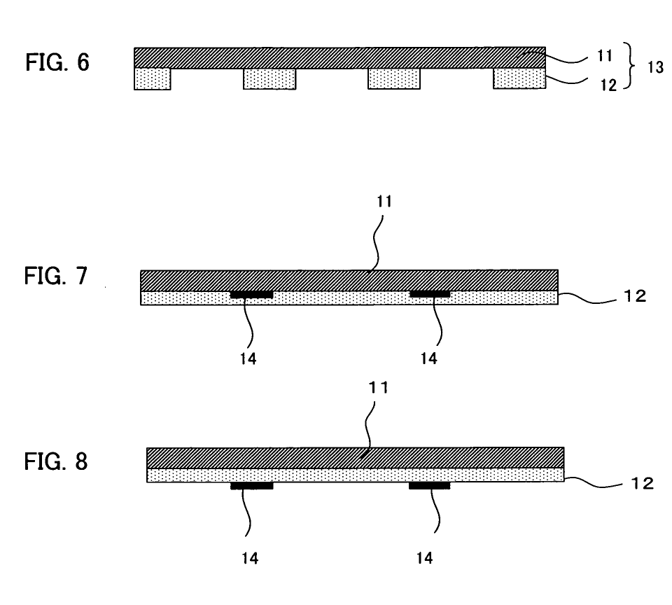

As shown in, for example, FIG. 5B, the photocatalyst-containing layer used in the invention may be formed on the whole of a surface of abase body 11. Alternatively, as shown in, for example, FIG. 6, a photocatalyst-containing layer 12 may be formed in a pattern form on a base body 11.

The formation of the photocatalyst-containing layer in a pattern form as described above makes the patterning irradiation using such as a photomask unnecessary, at the time of irradiating energy to form cell adhesion-inhibiting portions. Consequently, by irradiating the energy in a full surface, a pattern wherein the cell adhesive material comprised in the cell adhesive layer is decomposed or denatured can be formed.

The method for patterning the photocatalyst-containing layer is not particularly limited. For example, a method such as a photolithography may be used.

The cell adhesive material only on the cell adhesive layer which actually faces the photocatalyst-containing layer is decomposed or denatured; therefore, the direction in which energy is irradiated may be any direction if the energy is irradiated onto the area where the photocatalyst-containing layer and the cell adhesive layer face each other. There is generated an advantage that the irradiated energy is not particularly limited to energy composed of parallel constituents, such as parallel light rays.

As the photocatalyst that can be used in the present invention, specifically, for instance, titanium dioxide (TiO₂), zinc oxide (ZnO), tin oxide (SnO₂), strontium titanate (SrTiO₃), tungsten oxide (WO₃), bismuth oxide (Bi₂O₃) andiron oxide (Fe₂O₃) that are known as photo-semiconductors can be cited. These can be used singularly or in combination of at least two kinds.

In the present invention, in particular, titanium dioxide, owing to a large band gap, chemical stability, non-toxicity, and easy availability, can be preferably used. There are two types of titanium dioxide, anatase type and rutile type, and both can be used in the invention; however, the anatase type titanium dioxide is more preferable. An excitation wavelength of the anatase type titanium dioxide is 380 nm or less.

As such anatase type titanium dioxide, for instance, an anatase titania sol of hydrochloric acid deflocculation type (trade name: STS-O₂, manufactured by Ishihara Sangyo Kaisha, Ltd., average particle diameter: 7 nm, and trade name: ST-KO1, manufactured by Ishihara Sangyo Kaisha, Ltd.), an anatase titania sol of nitric acid deflocculation type (trade name: TA-15, manufactured by Nissan Chemical Industries Ltd., average particle diameter: 12 nm) and the like can be cited.

The smaller is a particle diameter of the photocatalyst, the better, because a photocatalyst reaction is caused more effectively. An average particle diameter of the photocatalyst is preferably 50 nm or less, and one having an average particle diameter of 20 nm or less can be particularly preferably used.

The photocatalyst-containing layer in the invention may be made of the photocatalyst alone as described above, or may be made of a mixture of the photocatalyst and a binder.

It is advantageous from the viewpoint of costs to use the photocatalyst-containing layer made only of a photocatalyst since the efficiency of decomposing or denaturing the cell adhesive material in the cell adhesive layer is improved to make the time for the treatment shorter or the like. On the other hand, the use of the photocatalyst-containing layer made of a photocatalyst and a binder gives an advantage of making the formation of the photocatalyst-containing layer easy.

An example of the method for forming the photocatalyst-containing layer made only of a photocatalyst may be a vacuum film-forming method such as sputtering, CVD or vacuum vapor deposition. The formation of the photocatalyst-containing layer by the vacuum film-forming method makes it possible to render the layer a homogeneous photocatalyst-containing layer made only of a photocatalyst, thereby decomposing or denaturing the cell adhesive material in the cell adhesive layer homogeneously, and further thereby making the decomposition or denaturation of the cell adhesive material more effective in this case than in the case of using a binder also since the layer is made only of the photocatalyst.

Another example of the method for forming the photocatalyst-containing layer made only of a photocatalyst, is the following method: in the case that the photocatalyst is, for example, titanium dioxide, amorphous titania is formed on the base material and next fired so as to phase-change the titania to crystalline titania. The amorphous titania used in this case can be obtained, for example, by hydrolysis or dehydration condensation of an inorganic salt of titanium, such as titanium tetrachloride or titanium sulfate, or hydrolysis or dehydration condensation of an organic titanium compound, such as tetraethoxytitanium, tetraisopropoxytitanium, tetra-n-propoxytitanium, tetrabutoxytitanium or tetramethoxytitanium, in the presence of an acid. Next, the resultant is fired at 400 to 500° C. so as to be denatured to anatase type titania, and fired at 600 to 700° C. so as to be denatured to rutile type titania.

In the case of using a binder together with the above-mentioned photocatalyst, the binder is preferably a binder having a high bonding energy, wherein its main skeleton is not decomposed by photoexcitation of the photocatalyst. Examples of such a binder include the organopolysiloxanes or the like.

In the case of using such an organopolysiloxane as the binder, the photocatalyst-containing layer can be formed by dispersing a photocatalyst, the organopolysiloxane as the binder, and optional additives if needed into a solvent to prepare a coating liquid, and applying this coating liquid onto the base body. The used solvent is preferably an alcoholic based organic solvent such as ethanol or isopropanol. The application can be performed by a known coating method such as spin coating, spray coating, dip coating, roll coating, or bead coating. When the coating liquid contains an ultraviolet curable component as the binder, the photocatalyst-containing layer can be formed by curing the coating liquid through the irradiation of ultraviolet rays onto the liquid.

As the binder, an amorphous silica precursor, a surfactant or the like may be used. Such a material may be the same as described in JP-A-2000-249821.

b. Base Body

The following will describe the base body used in the photocatalyst-containing layer side substrate. As shown in FIG. 5B, in the invention, the photocatalyst-containing layer side substrate has at least a base body 11, and a photocatalyst-containing layer 12 formed on this base body 11. In this case, the material which constitutes the used base body is appropriately selected in accordance with the direction of energy irradiation which will be detailed later, the matter as to whether or not transparency is necessary for the pattern-formed body to be yielded, or other factors.

The base body used in the invention may be a member having flexibility, such as a resin film, or may be a member having no flexibility, such as a glass plate. This is appropriately selected in accordance with the method for the energy irradiation.

An anchor layer may be formed on the base body in order to improve the adhesive property between the base body surface and the photocatalyst-containing layer. The anchor layer may be made of, for example, a silane-based or titanium-based coupling agent.

c. Photocatalyst-Containing Layer Side Light-Shielding Portions

The photocatalyst-containing layer side substrate used in the invention may be a photocatalyst-containing layer side substrate on which photocatalyst-containing layer side light-shielding portions may be formed into a pattern form. When the photocatalyst-containing layer side substrate having photocatalyst-containing layer side light-shielding portions is used in this way, it is unnecessary to use, at the time of irradiating energy, any photomask or to irradiate a laser ray for drawing irradiation. It is therefore unnecessary to position a photomask precisely onto the photocatalyst-containing layer side substrate. Consequently, it is unnecessary to use any complicated step or any expensive device for drawing irradiation, thereby producing an advantage for costs.

Such a photocatalyst-containing layer side substrate having photocatalyst-containing layer side light-shielding portions can be classified into the following two embodiments, depending on the position where the photocatalyst-containing layer light-shielding portions are formed.

One of them is an embodiment, for example, as shown in FIG. 7, wherein photocatalyst-containing layer side light-shielding portions 14 are formed on a base body 11 and a photocatalyst-containing layer 12 is formed on the photocatalyst-containing layer side light-shielding portions 14. The other example is an embodiment as shown in FIG. 8, wherein a photocatalyst-containing layer 12 is formed on a base body 11 and photocatalyst-containing layer side light-shielding portions 14 are formed on the layer 12.

In any one of the embodiments, the effect of energy-scattering in the base body or the like can be made smaller than in the case of using a photomask since the photocatalyst-containing layer side light-shielding portions are arranged near the region where the photocatalyst-containing layer and the cell adhesive layer are arranged. Accordingly, irradiation of energy in a pattern form can be more precisely attained.

In the invention, an embodiment wherein photocatalyst-containing layer side light-shielding portions 14 are formed on a photocatalyst-containing layer 12 as shown in FIG. 8 has an advantage that at the time of arranging the photocatalyst-containing layer and the cell adhesive layer in position, the film thickness of the light-shielding portions 14 can be made consistent with the width of the interval between the two layers, thereby using the light-shielding portions 14 as a spacer for making the interval constant.

In other words, when the photocatalyst-containing layer and the cell adhesive material layer are arranged so as to be facing each other at a given interval, the photocatalyst-containing layer side light-shielding portions and the cell adhesive layer can be made closely adhesive to each other, thereby making the dimension of the given interval precise. When the resultant in this state is irradiated with energy, cell adhesion-inhibiting portions can be formed with a good precision since no cell adhesive material is decomposed or denatured in the cell adhesive layer inside the region where the cell adhesive layer and the light-shielding portions contact.

The method for forming such photocatalyst-containing layer side light-shielding portions is not particularly limited, and may be appropriately selected in accordance with the property of the face where the light-shielding portions are to be formed, power for shielding required energy, and others. The light-shielding portions may be the same light-shielding portions as described in the item “B. Patterning Substrate” which are formed on a base material. Thus, detailed description thereof is omitted herein.

The above has described two cases, wherein the photocatalyst-containing layer side light-shielding portions are formed between the base body and the photocatalyst-containing layer and are formed on the surface of the photocatalyst-containing layer. Besides, the photocatalyst-containing layer side light-shielding portions may be formed on the base body surface on which no photocatalyst-containing layer is formed. In this embodiment, for example, a photomask can be made close to this surface to such a degree that the photomask can be put on and taken off. Thus, this embodiment can be preferably used for the case that the pattern of the cell adhesion-inhibiting portions is varied for every small lot.

d. Primer Layer

The following will describe a primer layer used in the photocatalyst-containing layer side substrate of the invention. When photocatalyst-containing layer side light-shielding portions are formed into a pattern form on a base body and a photocatalyst-containing layer is formed thereon in the invention so as to prepare a photocatalyst-containing layer side substrate described above, a primer layer may be formed between the photocatalyst-containing layer side light-shielding portions and the photocatalyst-containing layer.

The effect and function of this primer layer are not necessarily clear, but would be as follows: the primer layer is formed between the photocatalyst-containing layer side light-shielding portions and the photocatalyst-containing layer, whereby the primer layer exhibits a function of preventing the diffusion of impurities from openings which are present between the light-shielding portions, the impurities being factors for blocking the decomposition or denaturation of the cell adhesive material by action of the photocatalyst, in particular, residues generated when the photocatalyst-containing layer side light-shielding portions are patterned, or metal or metal ion impurities. Accordingly, the formation of the primer layer makes it possible that the processing of the decomposition or denaturation of the cell adhesive material advances with high sensitivity so as to yield cell adhesion-inhibiting portions which are highly precisely formed.

The primer layer in the invention is a layer for preventing the effect of the photocatalyst from being affected by the impurities present inside not only the photocatalyst-containing layer side light-shielding portions but also the openings made between the light-shielding portions. It is therefore preferred to form the primer layer over the entire surface of the light-shielding portions plus the openings.

The primer layer in the invention is not limited to any special structure if the primer layer is formed not to bring the photocatalyst-containing layer side light-shielding portions and the photocatalyst-containing layer of the photocatalyst-containing layer side substrate into contact with each other.

A material that forms the primer layer, though not particularly restricted, is preferably an inorganic material that is not likely to be decomposed by action of the photocatalyst. Specifically, amorphous silica can be cited. When such amorphous silica is used, a precursor of the amorphous silica is preferably a silicon compound that is represented by a general formula, SiX₄, X being halogen, methoxy group, ethoxy group, acetyl group or the like, silanol that is a hydrolysate thereof, or polysiloxane having an average molecular weight of 3000 or less.

A film thickness of the primer layer is preferably in the range of 0.001 to 1 μm and particularly preferably in the range of 0.001 to 0.1 μm.

(Irradiation of Energy)

The following will describe the irradiation of energy when the cell adhesion-inhibiting portions are formed. The irradiation of energy can be performed by arranging the above-mentioned cell adhesive layer and the photocatalyst-containing layer of the above-mentioned photocatalyst-containing layer side substrate to have a given interval therebetween and giving the energy to the resultant from a given side.

The above-mentioned wording “arranging” means that the above-mentioned two layers; the photocatalyst-containing layer and the cell adhesive layer are arranged in the state that the action of the photocatalyst can substantially work to the surface of the cell adhesive layer, and include not only the state that the two layers actually contact each other, but also the state that the two layers are arranged at a given interval. The dimension of the interval is preferably 200 μm or more.

The dimension of the above-mentioned interval in the invention is more preferably from 0.2 to 10 μm, even more preferably from 1 to 5 μm since the precision of the pattern to be obtained becomes very good and further the sensitivity of the photocatalyst becomes high so as to make good the efficiency of the decomposition or denaturation of the cell adhesive material in the cell adhesive layer. This range of the interval dimension is particularly effective for the cell adhesive layer small in area, which makes it possible to control the interval dimension with a high precision.

Meanwhile, in the case of treating the cell adhesive layer large in area, for example, 300 mm or more×300 mm or more in size, it is very difficult to make a fine interval as described above between the photocatalyst-containing layer side substrate and the cell adhesive layer without contacting each other. Accordingly, when the cell adhesive layer has a relatively large area, the interval dimension is preferably from 10 to 100 μm, more preferably from 50 to 75 μm. The limitation of the interval dimension into this range gives an advantageous effect that the cell adhesive material is not unevenly decomposed or denatured without causing problems based on a fall in patterning precision, such as a problem that a blurred pattern is obtained, or other problems, such as a problem that the sensitivity of the photocatalyst deteriorates so that the efficiency of decomposing or denaturing the cell adhesive material also deteriorates.

When energy is irradiated onto the cell adhesive material having a relatively large area as described above from an energy irradiating device, a unit for positioning the photocatalyst-containing layer side substrate and the cell adhesive layer inside the device is permitted to set the dimension of the interval therebetween preferably into the range of 10 to 200 μm, more preferably into the range of 25 to 75 μm. The setting of the interval dimension value into this range makes it possible to arrange the photocatalyst-containing layer side substrate and the cell adhesive layer without causing a large drop in patterning precision or in sensitivity of the photocatalyst, or bringing the substrate and the layer into contact with each other.

When the photocatalyst-containing layer and the surface of the cell adhesive layer are arranged at a given interval as described above, active oxygen species generated from oxygen and water by action of the photocatalyst can easily be released. In other words, if the interval between the photocatalyst-containing layer and the cell adhesive layer is made narrower than the above-mentioned range, the active oxygen species are not easily released, so as to make the rate for decomposing or denaturing the cell adhesive material unfavorably small. If the two layers are arranged at an interval larger than the above-mentioned range, the generated active oxygen species do not reach the cell adhesive layer easily. In this case also, the rate for decomposing or denaturing the cell adhesive material unfavorably becomes unfavorably small.

The method for arranging the photocatalyst-containing layer and the cell adhesive layer to make such a very small interval evenly therebetween is, for example, a method of using spacers. The use of the spacers in this way makes it possible to make an even interval. In regions which the spacers contact, the action of the photocatalyst does not work onto the surface of the cell adhesive layer; therefore, when the spacers are rendered spacers having a pattern similar to that of the cell adhesion portions, the cell adhesive material only inside regions where no spacers are formed can be decomposed or denatured so that highly precise cell adhesion-inhibiting portions can be formed. The use of the spacers also makes it possible that the active oxygen species generated by action of the photocatalyst reach the surface of the cell adhesive layer, without diffusing, at a high concentration. Accordingly, highly precise cell adhesion-inhibiting portions can be effectively formed.

In the invention, it is sufficient that such an arrangement state of the photocatalyst-containing layer side substrate is maintained only during the irradiation of energy.

The energy irradiation (exposure) mentioned in the present invention is a concept that includes all energy line irradiation that can decompose or denature the cell adhesive material by action of a photocatalyst on the basis of irradiation with energy, and is not restricted to light irradiation.

Normally, a wavelength of light used in such energy irradiation is set in the range of 400 nm or less, and preferably in the range of 380 nm or less. This is because, as mentioned above, the photocatalyst that is preferably used as a photocatalyst is titanium dioxide, and as energy that activates a photocatalyst action by the titanium oxide, light having the above-mentioned wavelength is preferable.

As a light source that can be used in such energy irradiation, a mercury lamp, metal halide lamp, xenon lamp, excimer lamp and other various kinds of light sources can be cited.

The method for the exposure may be a method of using a laser, such as an excimer laser or YAG laser, to draw and radiate energy in a pattern form, besides a method of using a light source as described above to draw and radiate energy in a pattern form through a photomask. When the base material has light-shielding portions in the same pattern form as the cell adhesion portions have, as described above, the exposure can be performed by irradiating the entire surface from the base material side thereof. When the photocatalyst-containing layer has thereon light-shielding portions in the same pattern form as the cell adhesion portions have, the exposure can be performed by irradiating the entire surface from any direction. These cases have an advantage that a photomask, and positioning and other steps are unnecessary.

When the base material has one or more concave portions and the cell adhesive layer is formed in the concave portion(s) as described above, energy may be irradiated onto the entire surface thereof by the above-mentioned method. In the case of the plural concave portions, for example, the exposure may be performed into the form of patterns different from each other for the individual concave portions. Examples of the method for performing the exposure into the form of patterns different from each other for the individual concave portions as described above include a method of arranging different masks for the individual concave portions to irradiate energy by use of the above-mentioned photocatalyst-containing layer side substrate; and a method of arranging the photocatalyst-containing layer side substrate and a chromium mask, a stencil mask or the like at the tip of an optical fiber to irradiate energy.

In order not to radiate any energy onto side walls of the concave portions, the method for the exposure may be, for example, a method of using a cylindrical mask to radiate energy only onto the bottom faces of the concave portions.

The irradiation quantity of the energy at the time of the energy-irradiation is set to a value necessary for decomposing or denaturing the cell adhesive material by action of the photocatalyst.

In this case, it is preferred to irradiate the photocatalyst-containing layer with the energy while heating the layer since the sensitivity can be raised so as to decompose or denature the cell adhesive material effectively. Specifically, the layer is preferably heated at a temperature of 30 to 80° C.

When the base material is transparent, the irradiation of energy through a photomask may be performed from either of the side of the base material and the side of the photocatalyst-containing layer side substrate. On the other hand, when the base material is opaque, energy needs to be irradiated from the side of the photocatalyst-containing layer side substrate.

e. Cell Culture Patterning Substrate

The following will describe the cell culture patterning substrate of the present invention. The cell culture patterning substrate is not limited to any special kind if the substrate is a member wherein a cell adhesive layer comprising the cell adhesion portion and the cell adhesion-inhibiting portion is formed on the base material, each of these constituents being defined above. If necessary, one or more different layers may be appropriately formed in the patterning substrate.

In the invention, the cell culture patterning substrate may be a member obtained by forming the above-mentioned cell adhesion-inhibiting portion, cutting one portion from the resultant cell culture patterning substrate, and attaching this portion onto the bottom or other part of a base material in a concave form.

D. Cell Culture Substrate

Next, a cell culture substrate in the invention will be explained. A cell culture substrate in the invention is one in which cells are adhered onto the cell adhesion portion in the above-mentioned cell culture patterning substrate.

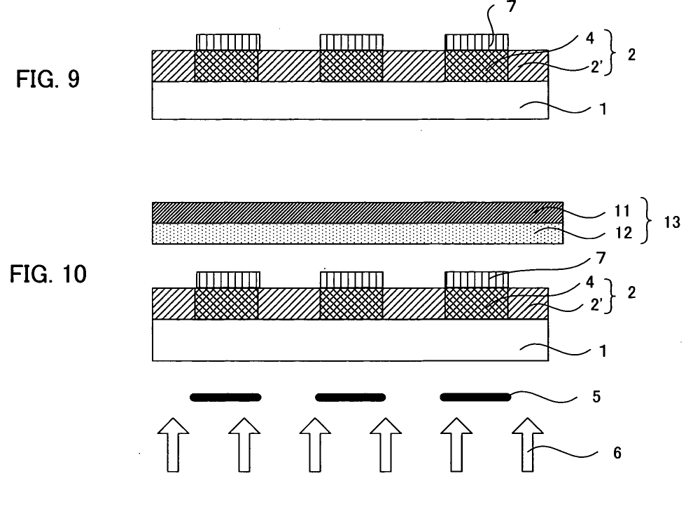

In the cell culture substrate in the invention, as shown in, for example, FIG. 9, cells 7 are adhered only onto a cell adhesion portion 2′ of the cell adhesive layer 2, and, on a cell adhesion-inhibiting portion 4, cells 7 are not adhered.

According to the invention, the cell adhesion portions good in cell adhesive properties and the cell adhesion-inhibiting portions having no cell adhesive properties are formed on the cell culture patterning substrate; for example, therefore, even if cells are applied onto the entire surface of the cell culture patterning substrate, the cells are caused to adhere only onto the cell adhesion portions and the cells on the cell adhesion-inhibiting portions can easily be removed. This makes it possible to form a cell pattern easily without using any complicated step or any treating solution or the like that produces a bad effect on the cells. Since the cell culture patterning substrate does not need to comprise therein any photocatalyst, the cells therein are not affected by any photocatalyst with the passage of time. Thus, the present cell culture substrate is a high-quality cell culture substrate.

According to the invention, for example, by arranging the photocatalyst-containing layer of the above-mentioned photocatalyst-containing layer side substrate to face the cell adhesive layer and then irradiating energy onto the entire surface of the cell culture substrate, the cell adhesive material of the cell adhesion portions onto which cells adhere can be decomposed or denatured so that the cell adhesive properties thereof can be made low. This makes it possible to peel easily the cells or the like adhering onto the cell adhesion portions so that only the cells formed in a pattern form can be obtained. The energy irradiated at this time is set into such a degree that the cells are not affected by the energy.

As described above, when light-shielding portions are formed in the same pattern form as the cell adhesion portions have on the base material, the cells adhering onto the cell adhesion-inhibiting portions can be removed, for example, by disposing the cell adhesive layer to face the photocatalyst-containing layer side substrate and optionally irradiating energy onto the entire surface of the resultant from the base material side thereof. As a result, the pattern where the cells adhere onto the cell adhesion portions can be maintained highly precisely.

When the light-shielding portions are not formed, a highly precise pattern can be maintained by disposing the photocatalyst-containing layer side substrate and the cell adhesive layer to face each other, and then irradiating energy onto the resultant through a photomask and the like wherein openings are made in the same pattern form as the cell adhesion-inhibiting portions have.

Hereinafter, cells that are used in a cell culture substrate in the invention will be explained. Since an explanation of a cell culture patterning substrate is the same as that in the “C. Cell Culture Patterning Substrate”, here it is omitted.

(Cells)

As cells used in a cell culture substrate in the invention, as far as cells can adhere onto a cell adhesion portion of the cell culture patterning substrate but do not adhere to a cell adhesion-inhibiting portion, there is no particular restriction.

As cells used in the present invention, except for, for instance, non-adhesive cells such as nervous tissue, liver, kidney, pancreas, blood vessel, brain, cartilage and blood corpuscle, all tissues present in an organism and cells derived therefrom can be used. Furthermore, since even for generally non-adhesive cells, recently, in order to adhere and fix, a technology of modifying a cell membrane is devised; accordingly, as needs arise, the non-adhesive cells, when this technology is applied, can be used in the present invention.

The respective tissues such as mentioned above are formed of cells having various functions; accordingly, it is necessary to select desired cells to use. For instance, in the case of the liver, it is formed of, other than hepatocytes, epithelial cells, endothelial cells, Kupffer's cells, fibroblasts, and fat-storing cells and the like. In this case, since the adhesive properties with a cell adhesive material is different depending on the kinds of the cells, in accordance with a cell strain, a cell adhesive material used in the cell adhesion portion and a composition ratio thereof have to be selected.

A method of adhering cells to the cell adhesion portion, as far as it can adhere cells only on the cell adhesion portion of the cell culture patterning substrate that has the cell adhesion portion and the cell adhesion-inhibiting portion, is not particularly restricted. For instance, cells may be adhered by use of an ink jet printer, a manipulator or the like; however, a method in which after a cell suspension is disseminated to adhere cells on the cell adhesion portion, unnecessary cells on a cell adhesion-inhibiting portion are washed with a phosphate buffer to remove the cells is generally used. As such a method, a method described in, for instance, a reference literature, Kevin E. Healy et al., “Spatial distribution of mammalian cells dicated by material surface chemistry”, Biotech. Bioeng. (1994), p. 792 can be used.

E. Method for Producing a Cell Culture Patterning Substrate

The following will describe the method of the invention for producing a cell culture patterning substrate. This method comprises a cell adhesive layer forming process of forming, on a base material, a cell adhesive layer comprising a cell adhesive material which has cell adhesive properties and is decomposed or denatured by action of a photocatalyst on the basis of irradiation with energy, and a binder; and
an energy irradiating process of arranging the cell adhesive layer and a photocatalyst-containing layer side substrate having a base body and a photocatalyst-containing layer comprising the photocatalyst to dispose the cell adhesive layer and the photocatalyst-containing layer facing each other, and subsequently irradiating the energy onto the resultant from a given direction to form a pattern composed of a cell adhesion-inhibiting portion where the cell adhesive material comprised in the cell adhesive layer is decomposed or denatured, and a cell adhesion portion which is other than the cell adhesion-inhibiting portion.

As shown in FIGS. 5A to 5C, the method of the invention for producing a cell culture patterning substrate comprises a cell adhesive layer forming process of forming a cell adhesive layer 2 comprising a cell adhesive material and a binder on a base material 1 (FIG. 5A); and an energy irradiating process of preparing a photocatalyst-containing layer side substrate 13 which has a base body 11 and a photocatalyst-containing layer 12 having a photocatalyst, arranging this cell adhesive layer 2 and the photocatalyst-containing layer 12 to be facing each other, and irradiating energy 6 onto the resultant through, for example, a photomask 5 (FIG. 5B), so as to form cell adhesion-inhibiting portions 4 where the cell adhesive material contained in the cell adhesive layer 2 inside the regions irradiated with the energy is decomposed or denatured and cell adhesion portions 2′ which are not irradiated with the energy and are good in cell adhesive properties (FIG. 5C).

According to the invention, the cell adhesive material contained in the cell adhesive layer can easily be decomposed or denatured by using the photocatalyst-containing layer side substrate to irradiate the energy. As a result, the cell adhesion portions and the cell adhesion-inhibiting portions can be formed in a highly precise pattern form. Since the cell adhesive layer does not need to comprise therein any photocatalyst, the cell culture patterning substrate can be rendered a high-quality cell culture patterning substrate which is not affected by any photocatalyst with the passage of time.

Each of the processes in the method of the invention will be described hereinafter.

1. Cell Adhesive Layer Forming Process

First, the cell adhesive layer forming process in the invention is described. The cell adhesive layer forming process in the invention is a process of forming, on a base material, a cell adhesive layer comprising a cell adhesive material which has cell adhesive properties and is decomposed or denatured by action of a photocatalyst on the basis of irradiation with energy, and a binder. In the invention, the process can be performed by using a coating liquid comprising the cell adhesive material and the binder and applying the coating liquid on a base material. The method for the application, constituent materials of the coating solution, and others are not specially limited. It is preferred to use, as the binder, a cell adhesion-inhibiting material having cell adhesion-inhibiting properties of inhibiting adhesion onto cells at least after the material is irradiated with energy. This makes it possible to make low the cell adhesive properties of the cell adhesion-inhibiting portion, which is a region irradiated with energy, in the energy irradiating process which will be detailed later, and further produce a cell culture patterning substrate onto which cells can be caused to adhere into a highly precise pattern form.

The cell adhesive material, the binder, the cell adhesion-inhibiting material and the base material used in the present process, and the method for forming the cell adhesive layer are equivalent to those described in the item “B. Patterning Substrate”. Thus, description thereof is omitted herein.

2. Energy Irradiating Process

The following will describe the energy irradiating process in the invention. This energy irradiating process is a process of arranging the cell adhesive layer and a photocatalyst-containing layer side substrate having a base body and a photocatalyst-containing layer comprising a photocatalyst to dispose the cell adhesive layer and the photocatalyst-containing layer facing each other, and subsequently irradiating the energy onto the resultant from a given direction to form a pattern composed of a cell adhesion-inhibiting portion where the cell adhesive material comprised in the cell adhesive layer is decomposed or denatured, and a cell adhesion portion which is other than the cell adhesion-inhibiting portion.

The manner for the present process is not limited to any special manner if the manner therefor is a manner of disposing the cell adhesive layer formed in the cell adhesive layer forming process and the photocatalyst-containing layer of the photocatalyst-containing layer side substrate to face each other and then irradiating energy in a pattern form onto the resultant to form a cell adhesion-inhibiting portion low in cell adhesive properties, where the cell adhesive material in the cell adhesive layer is decomposed or denatured.

The photocatalyst-containing layer side substrate and the energy irradiating method used in the present process may be those described in the item “C. Cell Culture Patterning Substrate”. Thus, detailed description thereof is omitted herein.

F. Method for Producing a Cell Culture Substrate

The following will describe the method of the invention for producing a cell culture substrate. This method is classified into two embodiments. Each of the embodiments will be described hereinafter.

### 1. First Embodiment

The first embodiment is first described. The method for producing a cell culture substrate according to the first embodiment comprises a cell adhesion process of adhering cells onto the cell adhesion portion of the cell culture patterning substrate produced by the method described in the item “E. Method for Producing a Cell Culture Patterning Substrate”.

According to the present embodiment, in the cell culture patterning substrate, the cell adhesion portion having cell adhesive properties and the cell adhesion-inhibiting portion having no cell adhesive properties are formed in the cell adhesive layer; therefore, for example, when cells are applied onto this cell adhesive layer, a cell culture substrate wherein the cells adhere only onto the cell adhesion portion can easily be produced. The cell culture patterning substrate does not need to comprise therein any photocatalyst; therefore, the cell culture substrate can be rendered a high-quality cell culture substrate wherein the cells are not affected by any photocatalyst with the passage of time.

The manner for the cell adhesion process in the present embodiment is not limited to any special manner if the manner is a manner capable of causing cells to adhere onto the cell adhesion portion. The manner may be a manner as described in the item “D. Cell Culture Substrate”. Thus, detailed description thereof is omitted herein.

### 2. Second Embodiment

The following will describe the second embodiment of the method of the invention for producing a cell culture substrate. The second embodiment is a method for producing a cell culture substrate comprising a base material, a cell adhesive layer formed on the base material and comprising a cell adhesive material which has cell adhesive properties and is decomposed or denatured by action of a photocatalyst on the basis of irradiation with energy and a binder, and cells formed in a pattern on the cell adhesive layer; the cell adhesive layer having a cell adhesion-inhibiting portion where the cell adhesive material is decomposed or denatured and a cell adhesion portion which is other than the cell adhesion-inhibiting portion, and the cells being formed on the cell adhesion portion;
comprising a cell adhesion process of causing the cells to adhere onto the cell adhesion portion, and
a subsequent cell maintaining process of arranging a photocatalyst-containing layer side substrate having a base body and a photocatalyst-containing layer comprising the photocatalyst onto the cell adhesion-inhibiting portion to dispose the cell adhesive layer and the photocatalyst-containing layer facing each other, and subsequently irradiating the energy onto the resultant from a given direction to maintain the pattern of the cells adhering onto the cell adhesion portion.

As shown in, for example, FIG. 10, the method of the present embodiment is a method for producing a cell culture substrate comprising a base material 1, a cell adhesive layer 2 having cell adhesion portions 2′ and cell adhesion-inhibiting portions 4, and cells 7 formed on the cell adhesion portions 2′. The present embodiment comprises a cell adhesion process of causing the cells 7 to adhere onto the cell adhesion portions 2′, and a subsequent cell maintaining process of preparing a photocatalyst-containing layer side substrate 13 wherein a photocatalyst-containing layer 12 is formed on a base body 11, arranging the photocatalyst-containing layer 12 and the cell adhesive layer 2 to be facing each other, and then irradiating energy 6 only onto the cell adhesion-inhibiting portions 4 through, for example, a photomask 5. This makes the following possible: even if cells adhere onto the cell adhesion-inhibiting portions, proteins, organic materials, the cells and others on the cell adhesion-inhibiting portions are removed by action of the photocatalyst contained in the photocatalyst-containing layer, so as to produce a cell culture substrate wherein the cells adhere highly precisely only onto the cell adhesion portions.

The following will describe the cell maintaining process in the method of the present embodiment for producing a cell culture substrate.

(Cell Maintaining Process)

The cell maintaining process in the method of the present embodiment for producing a cell culture substrate is performed after the cell adhesion process of causing cells to adhere onto the cell adhesion portion, and is a process of using a photocatalyst-containing layer side substrate to irradiate energy onto the cell adhesion-inhibiting portion, thereby maintaining the pattern of the cells adhering onto the cell adhesion portion. The method for irradiating the energy and the like is not specially limited if the method makes it possible to maintain the pattern of the cells on the cell adhesion portion highly precisely.

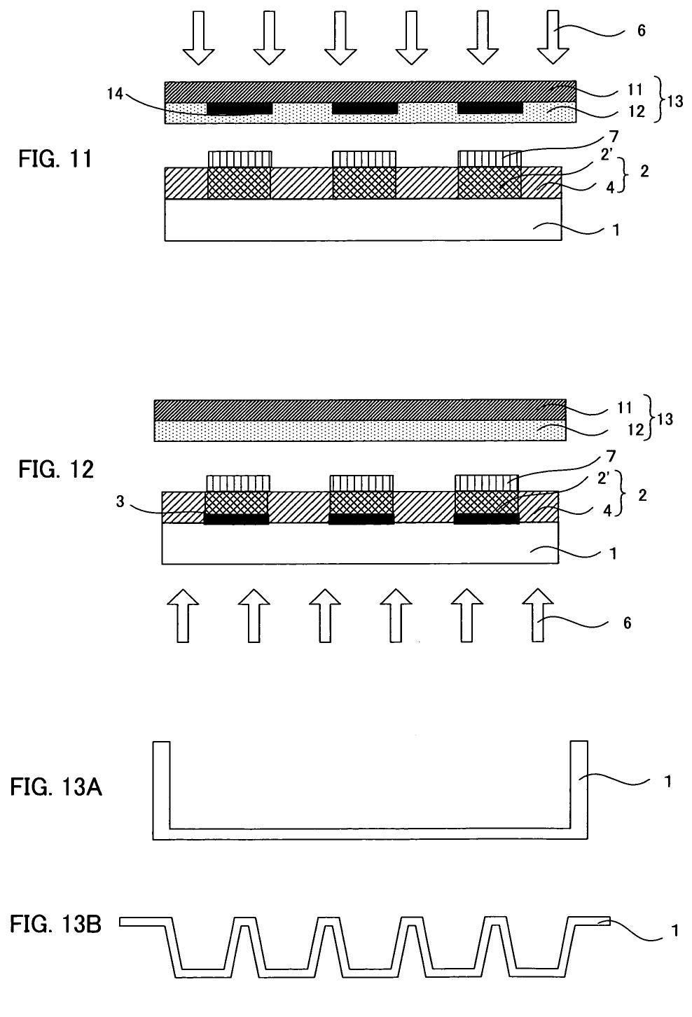

In the present embodiment, the energy irradiating method may be as follows: as shown in, for example, FIG. 10, a photocatalyst-containing layer 12 of a photocatalyst-containing layer side substrate 13 and the cell adhesive layer 2 are arranged to face each other, and then energy 6 is irradiated onto the resultant through such as a photomask 5 having openings in the same pattern as the cell adhesion-inhibiting portions have; as shown in, for example, FIG. 11, the cell adhesive layer 2 and a photocatalyst-containing layer 12 of a photocatalyst-containing layer side substrate 13, wherein light-shielding portions 14 are formed, are arranged to face each other, and then energy 6 is irradiated onto the entire surface of the resultant; or as shown in, for example, FIG. 12, when light-shielding portions 3 are formed in the same pattern as the cell adhesion portions 2′ have on the base material 1, the cell adhesive layer 2 and a photocatalyst-containing layer 12 are arranged to face each other, and then energy 6 is irradiated onto the entire surface of the resultant from the base material 1 side thereof, thereby irradiating the energy 6 only onto the cell adhesion-inhibiting portions 4.

The energy irradiated at this time is not limited to any special kind if the energy is energy capable of removing cells adhering onto the cell adhesion-inhibiting portions by action of the photocatalyst on the basis of the irradiation with the energy. Specifically, the energy may be the same energy as described about the method for forming a cell adhesive layer in the item “C. Cell Culture Patterning Substrate”. The photocatalyst-containing layer side substrate, the position where this photocatalyst-containing layer side substrate is arranged, and so on may be equivalent to those described about the method for forming a cell adhesive layer in the item “C. Cell Culture Patterning Substrate”. Thus, detailed description thereof is omitted herein.

As for a timing when the process is applied, it may be carried out immediately after the cell adhesion process of adhering cells on the cell adhesion portion is carried out, or when cells are cultured for a predetermined period on the cell adhesion portion, in order to avoid inconveniences such as that the cells adhere on the cell adhesion-inhibiting portion to result in a wide pattern and the like, in accordance with a kind and state of the cells, the timing may be properly selected. The process, also, may be repeated.

The cell adhesion process of causing cells to adhere onto the cell adhesion portion may be equivalent to the cell adhesion process in the above-mentioned first embodiment. Thus, description thereof is omitted herein.

(Others)

The method of the present embodiment for producing a cell culture substrate comprises, besides the energy irradiating process and the cell adhesion process, for example, the process of applying a coating liquid for patterning substrate comprising a photocatalyst and a cell adhesive material onto a base material to form a cell adhesive layer, the process of using a photocatalyst-containing layer side substrate to irradiate energy onto the cell adhesive layer to form a cell adhesion portion and a cell adhesion-inhibiting portion in the cell adhesive layer, and other optional processes.

The cell adhesive material, the base material and the photocatalyst-containing layer side substrate used in the present embodiment, the method for forming the cell adhesive layer, and so on are equivalent to those described in the item “E. Method for Producing a Cell Culture Patterning Substrate”. Thus, description thereof is omitted herein.

The present invention is not limited to the above-mentioned embodiments. The embodiments are mere examples. All modifications which have substantially the same structure as the technical conception described in the claims of the invention and produce effects and advantages similar to those of the technical conception are included in the technical scope of the invention.

### EXAMPLES

Hereinafter, examples are shown and thereby the present invention will be more specifically described.

### Example 1

(Formation of a Cell Adhesive Layer)

Three grams of isopropyl alcohol, 0.4 g of an organosilane, TSL 8114 (manufactured by GE Toshiba silicones), and 0.4 g of aminopropyltriethoxysilane were mixed, and then the mixture was heated at 100° C. for 20 minutes while stirred. This solution was applied onto a glass substrate subjected to alkali treatment in advance, 0.7 mm in thickness, by spin coating, and the substrate was dried at 150° C. for 10 minutes to advance hydrolysis and polycondensation reaction, thereby forming, on the substrate, an organopolysiloxane layer, about 80 nm in thickness, containing amino groups. In this way, a patterning substrate was produced.

(Patterning of the Patterning Substrate)

A photomask on which a photocatalyst layer was formed was allowed to stand still onto the patterning substrate to dispose the photocatalyst layer and the cell adhesive layer of this patterning substrate facing each other. Ultraviolet rays were irradiated from a mercury lamp, through the photomask, onto this patterning substrate at 15 J/cm² (wavelength: 254 nm) to yield a cell culture patterning substrate having a cell adhesive surface patterned so as to have unexposed portions having cell adhesive properties and exposed portions having cell adhesion-inhibiting properties.

(Cell Adhesion Process)

About the process of experiments for culturing cells originating from various kinds of tissues, details thereof are described in, for example, “Soshikibaiyo no Gijyutsu, Dai San Han, Kiso”, edited by The Japanese Tissue Culture Association and published by Asakura Shoten, and other documents.

In the present application, rat hepatocytes were used to evaluate the cell culture patterning substrate.

A liver extracted from a rat was transferred into a Petri dish, and the liver was cut into pieces 5 mm in size with a scalpel. Thereto was added 20 ml of a DMEM culture medium, and the pieces were lightly suspended with a pipette. Thereafter, the suspension was filtrated with a cell filter. The resultant cell-coarsely-dispersed suspension was subjected to centrifugation at 500 to 600 rpm for 90 seconds, and the supernatant was sucked to be removed. A new DMEM culture medium was added to the remaining cells, and the resultant was again subjected to centrifugation. This operation was repeated three times to yield substantially homogenous hepatocytes. To the resultant hepatocytes was added 20 ml of a DMEM culture medium, and the cells were suspended therein to prepare a hepatocytes suspension.

Next, 900 ml of distilled water was added to 14.12 g of a Waymouth MB 752/1 culture medium (containing L-glutamine but containing no NaHCO₃) (manufactured by GIBCO). To this were added 2.24 g of NaHCO₃, 10 ml of an amphotericin B solution (ICN), and 10 ml of a penicillin streptomycin solution (manufactured by GIBCO), and this solution was stirred. This was adjusted into a pH of 7.4, and then the total amount thereof was set to 1000 ml. The resultant was filtrated with a 0.22 μm membrane filter and sterilized to prepare a Waymouth MB 752/1 culture medium solution.

The previously-prepared hepatocytes suspension was suspended into the prepared Waymouth MB 752/1 culture medium solution, and further the resultant suspension was inoculated onto the above-mentioned cell culture patterning substrate, which had the cell adhesion portions and the cell adhesion-inhibiting portions. This substrate was allowed to stand still in an incubator to which 5% CO₂ was supplied at 37° C. for 24 hours to cause the hepatocytes to adhere onto the entire surface of the substrate. This substrate was washed with PBS two times to remove non-adhering cells and dead cells. Thereafter, the culture medium solution was exchanged for a new culture medium solution. While the exchange of the culture medium solution was repeated, the cells were continued to be cultured for 48 hours. The cells were then observed with an optical microscope. As a result, it was found out that the cells adhered along the cell adhesion portions of the cell culture patterning substrate.

### Example 2

A hole of 14 mm diameter was made at the center of the bottom face of a commercially available plastic dish (manufactured by Corning Inc.) of 35 mm diameter. Subsequently, a glass substrate of about 0.1 mm thickness was used to form a cell culture patterning substrate in the same way as in Example 1. This cell culture patterning substrate was cut into a 21 mm square. Thereafter, the glass substrate of the cut cell culture patterning substrate was stuck onto the above-mentioned plastic dish through an adhesive agent, KE45T (Shin-Etsu Chemical Co., Ltd).

(Adhesion of Cells)

The plastic dish was sterilized with 70% ethanol, and washed with PBS. Thereafter, the dish was washed with a DMEM culture medium. Cells were then cultured in the same way as in Example 1. As a result, it was found out that the cells adhered along the cell adhesion portions in the plastic dish.

1. A patterning substrate, comprising: a base material; and a cell adhesive layer formed on the base material and comprising a cell adhesive material which has cell adhesive properties and is decomposed or denatured by action of a photocatalyst on a basis of irradiation with energy, and a binder.

2. The patterning substrate according to claim 1, wherein a light-shielding portion is formed on the base material.

3. A cell culture patterning substrate, wherein the cell adhesive layer of the patterning substrate according to claim 1 comprises a cell adhesion-inhibiting portion wherein the cell adhesive material is decomposed or denatured in a pattern form and a cell adhesion portion which is a region other than the cell adhesion-inhibiting portion.

4. A cell culture patterning substrate, wherein the cell adhesive layer of the patterning substrate according to claim 2 comprises a cell adhesion-inhibiting portion wherein the cell adhesive material is decomposed or denatured in a pattern form and a cell adhesion portion which is a region other than the cell adhesion-inhibiting portion.

5. A cell culture substrate, wherein cells adhere onto the cell adhesion portion of the cell culture patterning substrate according to claim 3.

6. A cell culture substrate, wherein cells adhere onto the cell adhesion portion of the cell culture patterning substrate according to claim 4.

7. A coating liquid for patterning substrate, comprising a cell adhesive material which has cell adhesive properties and is decomposed or denatured by action of a photocatalyst on a basis of irradiation with energy, and a cell adhesion-inhibiting material having cell adhesion-inhibiting properties of inhibiting adhesion to cells at least after the material is irradiated with the energy.

8. A method for producing a cell culture patterning substrate, comprising a cell adhesive layer forming process of forming, on a base material, a cell adhesive layer comprising a cell adhesive material which has cell adhesive properties and is decomposed or denatured by action of a photocatalyst on a basis of irradiation with energy, and a binder; and
an energy irradiating process of arranging the cell adhesive layer and a photocatalyst-containing layer side substrate having a base body and a photocatalyst-containing layer comprising the photocatalyst to dispose the cell adhesive layer and the photocatalyst-containing layer facing each other, and subsequently irradiating the energy onto a resultant from a given direction to form a pattern composed of a cell adhesion-inhibiting portion where the cell adhesive material comprised in the cell adhesive layer is decomposed or denatured, and a cell adhesion portion which is other than the cell adhesion-inhibiting portion.

9. A method for producing a cell culture substrate, comprising a cell adhesion process of causing cells to adhere onto the cell adhesion portion of the cell culture patterning substrate produced by the method according to claim 8.

10. A method for producing a cell culture substrate comprising a base material, a cell adhesive layer formed on the base material and comprising a cell adhesive material which has cell adhesive properties and is decomposed or denatured by action of a photocatalyst on a basis of irradiation with energy and a binder, and cells formed in a pattern on the cell adhesive layer; the cell adhesive layer having a cell adhesion-inhibiting portion where the cell adhesive material is decomposed or denatured and a cell adhesion portion which is other than the cell adhesion-inhibiting portion, and the cells being formed on the cell adhesion portion;
comprising a cell adhesion process of causing the cells to adhere onto the cell adhesion portion, and
a subsequent cell maintaining process of arranging a photocatalyst-containing layer side substrate having a base body and a photocatalyst-containing layer comprising the photocatalyst onto the cell adhesion-inhibiting portion to dispose the cell adhesive layer and the photocatalyst-containing layer facing each other, and subsequently irradiating the energy onto a resultant from a given direction to maintain the pattern of the cells adhering onto the cell adhesion portion.
